(19) United States
(12) Patent Application Publication
(10) Pub. No.: US 2025/0076136 A1
(43) Pub. Date: Mar. 6, 2025

(54) FULL-KEYBOARD KEY PRESSURE TESTING EQUIPMENT

(71) Applicant: Peratech Electronic Tech Suzhou Co Ltd, Suzhou (CN)

(72) Inventors: Zefeng Li, Suzhou (CN); Jiajun Tang, Suzhou (CN); Jiongbin Zhang, Suzhou (CN); Shuping Sun, Suzhou (CN); Piao Yang, Suzhou (CN)

(73) Assignee: Peratech Electronic Tech Suzhou Co Ltd, Suzhou (CN)

(21) Appl. No.: 18/933,917

(22) Filed: Oct. 31, 2024

(30) Foreign Application Priority Data
Aug. 31, 2023 (CN) 202311109775.8

(51) Int. Cl. G01L 5/22; G01D 11/02; G01D 11/18; G06F 3/02

(52) U.S. Cl. CPC G01L 5/22; G01D 11/02; G01D 11/18; G06F 3/0202

(57) ABSTRACT

A device for testing pressure of keys of a full keyboard includes a variable-pitch test module mechanism. The variable-pitch test module mechanism includes multiple modules mounted on a base plate and probe modules provided corresponding to the variable-pitch test modules one by one; the variable-pitch test module includes a first driving device and a second driving device, the probe module is mounted on the second driving device, the second driving device is provided on the first driving device, the first driving device is configured to adjust a position of the probe module in an X direction, and the second driving device is configured to adjust a position of the probe module in a Y direction; and the probe module includes a lifting device and a probe for testing. The lifting device is connected to the probe and is configured to adjust a position of the probe in a Z direction.

### TECHNICAL FIELD

The present invention relates to the technical field of devices for testing keyboards, and particularly to a device for testing pressure of keys of a full keyboard.

### BACKGROUND ART

With the progress of science and technology and the development of modern electronic technique, people's requirements for key input cannot be satisfied by conventional computer keyboards. Multi-functional human-computer interaction experience can meet customized input requirements of users, and thus keyboards with pressure induction are getting more and more popular among users. Compared with conventional keyboards, pressure keyboards have a capability of pressure induction, and can convert pressures on a key transmitted by a user's finger into different degrees of signals, so that input forms of an electronic device become more varied. A device for testing and calibrating pressure keyboards is different from a device for testing the conventional keyboards, and a pressure application process and a signal collection process thereof both require a long time, which presents a challenge to the device for testing the pressure keyboards.

The existing devices for testing keyboards have a single function, and cannot have functions of testing key stroke, key resistance value and key pressure at the same time. For testing a keyboard with a pressure function, signal collection needs to be performed in an entire pressure range in an application process of product, while existing testing devices usually use a fixed counterweight to apply pressure and cannot meet an existing test range. In addition, restricted by space, the existing devices mainly use a single probe (testing head) to test the full keyboard, which affects testing efficiency, and the devices are bulky and occupy factory space. Some other devices use a plurality of probes to test the full keyboard, but a driving module uses a synchronous belt, which affects positioning accuracy.

### SUMMARY

The present invention aims at providing a device for testing pressure of keys of a full keyboard, so as to alleviate problems of low testing efficiency and poor positioning accuracy of existing keyboard testing devices.

In order to solve the above technical problems, the present invention provides following technical solutions.

A device for testing pressure of keys of a full keyboard includes a variable-pitch test module mechanism, wherein the variable-pitch test module mechanism includes a plurality of variable-pitch test modules mounted on a base plate and probe modules provided corresponding to the variable-pitch test modules one by one;
the variable-pitch test module includes a first driving device and a second driving device, the probe module is mounted on the second driving device, the second driving device is provided on the first driving device, the first driving device is configured to adjust a position of the probe module in an X direction, and the second driving device is configured to adjust a position of the probe module in a Y direction; and
the probe module includes a lifting device and a probe for testing, wherein the lifting device is connected to the probe and is configured to adjust a position of the probe in a Z direction.

Further, the base plate is mounted with a guide-shaft fixing plate, the variable-pitch test module further includes a lead screw module base connected to the base plate, and the first driving device includes a guide structure and an adjustment structure which are provided between the lead screw module base and the guide-shaft fixing plate.

Further, the guide structure includes a bushing and a guide shaft, the bushing being provided in a through hole of the lead screw module base and the guide shaft penetrating through the bushing.

Further, the adjustment structure includes an adjustment bolt connected between the lead screw module base and the guide-shaft fixing plate.

Further, the guide-shaft fixing plate is provided with a limiting groove configured for limiting the adjustment bolt in the X direction.

Further, the second driving device includes a motor and a lead screw module, wherein the lead screw module is mounted on the lead screw module base, the lead screw module is connected to the probe module, the motor is in transmission connection with the lead screw module, and the motor drives the lead screw module to move in the Y direction.

Further, the lead screw module is connected to a slider base, the slider base is mounted with a probe module fixing block, and the lifting device is provided on the probe module fixing block.

Further, the lifting device includes a guide rail, a pressure sensor fixing block and a pressure sensor, wherein the guide rail is provided on the probe module fixing block, the pressure sensor fixing block is slidably connected to the guide rail, and the pressure sensor has one end connected to the pressure sensor fixing block and the other end connected to the probe.

Further, a preloaded spring is provided between the probe module fixing block and the pressure sensor fixing block, and the preloaded spring is in a compressed state so as to apply a preloaded force to the probe.

Further, the probe module fixing block is mounted with a lifting cylinder, wherein the lifting cylinder is connected to the pressure sensor fixing block and is configured to lift the probe to an avoidance height in the Z direction.

The present invention at least gives the following beneficial effects.

The present invention provides a device for testing pressure of keys of a full keyboard, including a variable-pitch test module mechanism, wherein the variable-pitch test module mechanism includes a plurality of variable-pitch test modules mounted on a base plate and probe modules provided corresponding to the variable-pitch test modules one by one; the variable-pitch test module includes a first driving device and a second driving device, the probe module is mounted on the second driving device, the second driving device is provided on the first driving device, the first driving device is configured to adjust a position of the probe module in an X direction, and the second driving device is configured to adjust a position of the probe module in a Y direction; and the probe module includes a lifting device and a probe for testing, wherein the lifting device is connected to the probe and is configured to adjust a position of the probe in a Z direction.

The variable-pitch test module mechanism includes a plurality of variable-pitch test modules each being provided with the probe in one-to-one correspondence, and thus the plurality of probes may simultaneously test the full keyboard, thereby improving testing efficiency. Before testing pressure of keys of the full keyboard, an interval of the plurality of probes in the X direction is adjusted by the first driving devices first according to a row spacing of the keys of the tested keyboard. Then according to an interval of each row of keys of the tested keyboard in the Y direction, a control program is compiled and imported into the device for testing pressure of keys of a full keyboard. When testing the pressure of keys of the full keyboard, the second driving device can adjust positions of the probes in the Y direction in real time according to the control program, and after the probes are adjusted into place, the lifting devices control heights of the probes in the Z direction and perform variable-pitch test, so as to quickly and efficiently complete the test for the pressure of the keys of the full keyboard. The variable-pitch test modules control movement of the probes using lead screw modules, thus improving positioning accuracy.

In order to make the above objectives, features and advantages of the present invention more obvious and understandable, preferred embodiments are particularly illustrated below in combination with drawings to make following detailed description.

### BRIEF DESCRIPTION OF DRAWINGS

In order to more clearly illustrate the technical solutions in the embodiments of the present invention or in the related art, drawings which need to be used in the description of the embodiments or the related art will be introduced briefly below. Apparently, the drawings in the following description are merely for some embodiments of the present invention, and those ordinarily skilled in the art still could obtain other drawings in light of these drawings without using any inventive efforts.

FIG. 1 is a first schematic view of a variable-pitch test module mechanism provided by embodiments of the present invention;

FIG. 2 is a second schematic view of the variable-pitch test module mechanism provided by embodiments of the present invention; and

FIG. 3 is a structural schematic view of a probe module provided by embodiments of the present invention.

### REFERENCE SIGNS

100-base plate; 200-guide-shaft fixing plate; 210-limiting groove; 310-lead screw module base; 320-bushing; 330-guide shaft; 340-adjustment bolt; 410-motor; 420-lead screw module; 430-slider base; 510-probe module fixing block; 520-guide rail; 530-pressure sensor fixing block; 540-pressure sensor; 550-probe; 560-probe base; 570-preloaded spring; 580-lifting cylinder.

### DETAILED DESCRIPTION OF EMBODIMENTS

Technical solutions of the present invention will be described below clearly and completely in conjunction with drawings. Apparently, only some but not all embodiments of the present invention are described. Based on the embodiments of the present invention, all of other embodiments obtained by those skilled in the art without any inventive efforts shall fall within the scope of protection of the present invention.

It should be noted that like reference signs and letters represent like items in the following drawings. Therefore, once a certain item is defined in one drawing, it is not needed to be further defined or explained in subsequent drawings.

In the description of the present invention, it should be noted that orientation or positional relationships indicated by terms such as “center”, “upper”, “lower”, “left”, “right”, “vertical”, “horizontal”, “inner”, and “outer” are based on orientation or positional relationships as shown in the drawings, merely for facilitating describing the present invention and simplifying the description, rather than indicating or implying that related devices or elements have to be in the specific orientation, or configured and operated in a specific orientation, and thus they should not be construed as limitation to the present invention. Besides, the terms “first”, “second”, and “third” are merely for descriptive purpose, but should not be construed as indicating or implying importance in relativity. Physical quantities in formulas, if not individually labeled, are to be understood as basic quantities of basic units of the international system of units, or derived quantities derived from the basic quantities by mathematical operations such as multiplication, division, differentiation or integration.

In addition, the terms such as “horizontal”, “vertical”, and “overhanging” do not mean that a component is required to be absolutely horizontal or overhanging, but may be slightly inclined. For example, by “horizontal” it merely means that a structure is more horizontal in direction in comparison with “vertical”, rather than being completely horizontal, while the structure may be slightly inclined.

In the description of the present invention, it should also be noted that unless otherwise expressly specified or defined, the terms “provide”, “mount”, “couple”, and “connect” should be understood in a broad sense. For example, a connection may be a fixed connection or detachable connection or integral connection, may be a mechanical connection or electric connection, or may be direct coupling or indirect coupling via an intermediary or internal communication between two elements. For those ordinarily skilled in the art, specific meanings of the above-mentioned terms in the present invention can be understood in specific situations.

Some embodiments of the present invention are described in detail below in conjunction with the drawings. The following embodiments and features in the embodiments may be combined with each other without conflict.

### Embodiment 1

Existing testing devices use a fixed counterweight to apply pressure and cannot meet an existing test range. In addition, restricted by space, the existing devices mainly use a single probe to test a full keyboard, which affects testing efficiency, and the devices are bulky and occupy factory space. Some other devices use a plurality of probes to test the full keyboard, but a driving module uses a synchronous belt, which affects positioning accuracy.

In view of this, embodiments of the present invention provide a device for testing pressure of keys of a full keyboard, including: a variable-pitch test module mechanism, wherein the variable-pitch test module mechanism includes a plurality of variable-pitch test modules mounted on a base plate 100 and probe modules provided corresponding to the variable-pitch test modules one by one; the variable-pitch test module includes a first driving device and a second driving device, the probe module is mounted on the second driving device, the second driving device is provided on the first driving device, the first driving device is configured to adjust a position of the probe module in an X direction, and the second driving device is configured to adjust a position of the probe module in a Y direction; and the probe module includes a lifting device and a probe 550 for testing, wherein the lifting device is connected to the probe 550 and is configured to adjust a position of the probe 550 in a Z direction.

The variable-pitch test module mechanism includes a plurality of variable-pitch test modules each being provided with the probe 550 in one-to-one correspondence, and thus the plurality of probes 550 may simultaneously test the full keyboard, thereby improving testing efficiency. Before testing pressure of keys of the full keyboard, an interval of the plurality of probes 550 in the X direction is first adjusted by the first driving devices according to a row spacing of the keys of the tested keyboard. Then according to an interval of each row of keys of the tested keyboard in the Y direction, a control program is compiled and imported into the device for testing pressure of keys of a full keyboard. When testing the pressure of keys of the full keyboard, the second driving device can adjust positions of the probes 550 in the Y direction in real time according to the control program, and after the probes are adjusted into place, the lifting devices control heights of the probes 550 in the Z direction and performs variable-pitch test, so as to quickly and efficiently complete the test for the pressure of the keys of the full keyboard. The variable-pitch test modules control movement of the probes 550 using lead screw modules 420, thus improving positioning accuracy.

It should be noted that, in order to be adapted to a structure of the keyboard, the variable-pitch test module mechanism in the present embodiment includes six variable-pitch test modules, six probes 550 are correspondingly provided, and six rows of keys of the keyboard can be simultaneously tested. Moreover, three variable-pitch test modules are provided on one side of the base plate 100, and the other three variable-pitch test modules are provided on the other side of the base plate 100. Such opposite arrangement is due to the fact that the lead screw module 420 is relatively wide while the row spacing of each row of keys on the keyboard is relatively small, so that a problem of limited space of the lead screw module 420 in a width direction is overcome.

In an optional mode of the present embodiment, the base plate 100 is mounted with a guide-shaft fixing plate 200, the variable-pitch test module further includes a lead screw module base 310, the lead screw module base 310 is connected to the base plate 100, and the first driving device includes a guide structure and an adjustment structure which are provided between the lead screw module base 310 and the guide-shaft fixing plate 200.

With reference to FIG. 2, two sides of the base plate 100 are each provided with a guide-shaft fixing plate 200, and the lead screw module base 310 is mounted on the base plate 100. By the adjustment structure, the position of the lead screw module base 310 in the X direction may be adjusted, so as to realize adjustment of the positions of the probes 550 in the X direction. The guide structure provides a guiding function for the lead screw module base 310 in the X direction, so that the lead screw module base 310 moves in the X direction all the time during the adjustment of the adjustment structure.

Specifically, the guide structure includes a bushing 320 and a guide shaft 330, the bushing 320 being provided in a through hole of the lead screw module base 310 and the guide shaft 330 penetrating through the bushing 320.

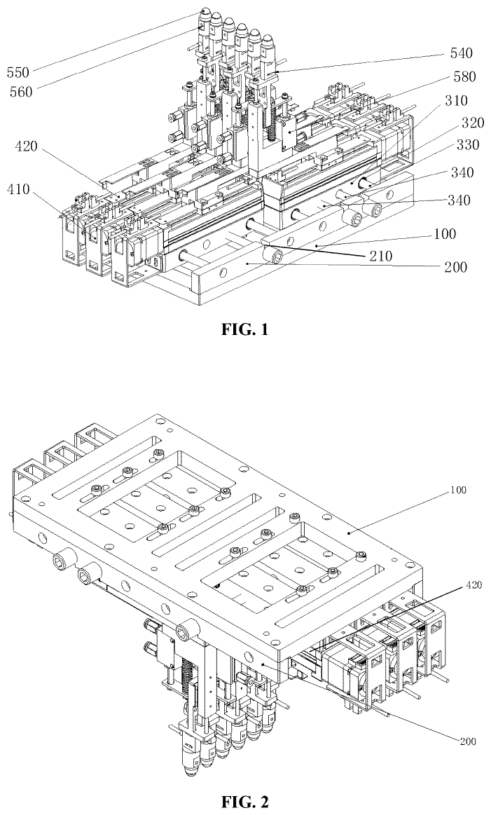

Referring to FIG. 1, four linear guide shafts 330 are mounted between the two guide-shaft fixing plates 200, and six lead screw module bases 310 mounted with bushings 320 are symmetrically mounted on the guide shafts 330. In the above, one lead screw module base 310 serves as a reference and is fixed on the base plate 100 by bolts, and the other five lead screw module bases 310 realize a guiding movement in the X direction through the bushings 320 and the guiding shafts 330.

Further, the adjustment structure includes adjustment bolts 340, the adjustment bolts 340 being connected between the lead screw module bases 310 and the guide-shaft fixing plates 200.

With continued reference to FIG. 1, five lead screw module bases 310 are connected to the guide-shaft fixing plates 200 by five adjustment bolts 340 of different lengths respectively, and distances between the lead screw module bases 310 and the guide-shaft fixing plates 200 may be adjusted by rotating the adjustment bolts 340. The guide-shaft fixing plates 200 are provided with limiting grooves 210 for limiting the adjustment bolts 340 in the X direction. The limiting grooves 210 are U-shaped grooves, and can limit movement of the lead screw module bases 310 in the X direction. When the lead screw module bases 310 are adjusted to proper positions, the lead screw module bases 310 may be locked and fixed by locking bolts.

In an optional mode of the present embodiment, the second driving device includes a motor 410 and a lead screw module 420, wherein the lead screw module 420 is mounted on the lead screw module base 310, the lead screw module 420 is connected to the probe module, the motor 410 is in transmission connection with the lead screw module 420, and the motor 410 drives the lead screw module 420 to move in the Y direction.

With reference to FIG. 1, the six lead screw module bases 310 are fixed with six lead screw modules 420 by bolts and pins, and the six lead screw modules 420 are correspondingly provided with six motors 410, wherein output shafts of the motors 410 are in transmission connection with the lead screw modules 420, and the lead screw modules 420 are driven by the motors 410 to move in the Y direction, thus realizing adjustment of the positions of the probes 550 in the Y direction.

Further, the lead screw module 420 is connected to a slider base 430, the slider base 430 is mounted with a probe module fixing block 510, and the lifting device is provided on the probe module fixing block 510.

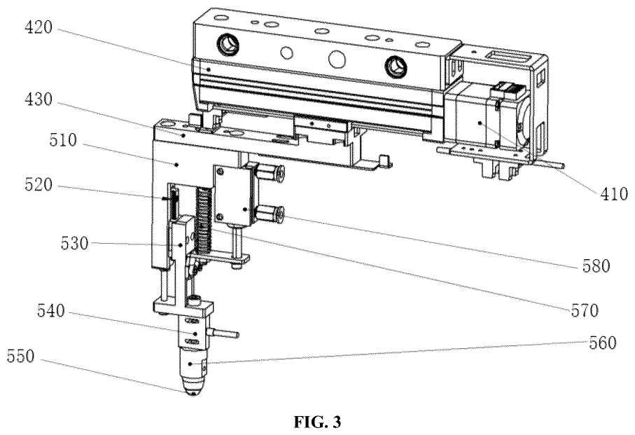

With reference to FIG. 3, the lifting device realizes connection with the lead screw module 420 through the probe module fixing block 510 and the slider base 430, so that when the lead screw module 420 moves in the Y direction, the probe 550 can synchronously move in the Y direction.

In an optional mode of the present embodiment, the lifting device includes a guide rail 520, a pressure sensor fixing block 530 and a pressure sensor 540, wherein the guide rail 520 is provided on the probe module fixing block 510, the pressure sensor fixing block 530 is slidably connected to the guide rail 520, and the pressure sensor 540 has one end connected to the pressure sensor fixing block 530 and the other end connected to the probe 550.

With continued reference to FIG. 3, the guide rail 520 is a linear guide rail 520 capable of guiding up-down movement of the probe 550 in the Z direction. The probe 550 is fixedly mounted on the pressure sensor 540 through a probe base 560, the pressure sensor 540 is mounted on the pressure sensor fixing block 530, and the pressure sensor fixing block 530 is slidably mounted on the guide rail 520. During test, the pressure sensor 540 may receive pressure data in real time, and collect a feedback force of the key of the keyboard, thereby realizing the test for the pressure keyboard.

In an optional mode of the present embodiment, a preloaded spring 570 is provided between the probe module fixing block 510 and the pressure sensor fixing block 530, and the preloaded spring 570 is in a compressed state so as to apply a preloaded force to the probe 550.

A design requirement to the preloaded force of the preloaded spring 570 depends on a testing range of tested keys, and generally, the testing range of pressure of keys of the pressure keyboard is 0-5 N. In order to ensure that the probe 550 may not generate vibration deviation during the test of pressure key to affect accuracy of data acquisition, the preloaded spring 570 is mounted on an upper side of the pressure sensor fixing block 530 in a compressed state, and a spring force thereof in the compressed state is greater than a maximum key testing force. In this state, when the probe 550 performs a normal test, parts such as the pressure sensor fixing block 530, the pressure sensor 540 and the probe 550 may not generate relative displacement with respect to the guide rail 520 and the probe module fixing block 510, and a structural state of the test is stable. When the probe 550 is subjected to a set limit pressure value, in order to protect the pressure sensor 540 from damage by hard impact, the preloaded spring 570 can play a buffering role.

In an optional mode of the present embodiment, the probe module fixing block 510 is mounted with a lifting cylinder 580, wherein the lifting cylinder 580 is connected to the pressure sensor fixing block 530 and is configured to lift the probe 550 to an avoidance height in the Z direction.

The lifting cylinder 580 is controlled by a computer via an electromagnetic valve. Since the number of keys on each horizontal row of the keyboard is unequal, and the pressure keyboard itself has a characteristic of resistance value change after key pressing, once keys located on a same driving line on a data acquisition card of the pressure keyboard are simultaneously pressed, data interference may occur and affect the test, and thus the program needs to control to skip testing positions of some keys in some testing steps. In a process of testing the keyboard, if a position requiring no test is encountered, the lifting cylinder 580 can lift the probe 550 to the avoidance height in the Z direction, so as to avoid testing at that position. Each probe 550 can be independently controlled and lifted up, to selectively participate in a multi-probe test, so that keys interfering with data acquisition can be effectively avoided. In practical tests, in order to avoid interference keys and satisfy layout with different numbers of keys in each row, in each testing step of a whole test procedure, it needs to control and adjust intervals of various probes 550 in the Y direction by varied pitches of the lead screw module 420 as required, and lift the height of the probe 550 in the Z direction through synergistic cooperation of the lifting cylinder 580, so as to efficiently complete the test.

The device for testing pressure of keys of a full keyboard provided by the present embodiment can efficiently and accurately complete the test for pressure-stroke-output signal of each pressure key of the keyboard.

Finally, it should be noted that: various examples above are merely used for illustrating the technical solutions of the present invention, rather than limiting the present invention; while the detailed description is made to the present invention with reference to various preceding embodiments, those ordinarily skilled in the art should understand that they still could modify the technical solutions described in the various preceding embodiments, or make equivalent substitutions to some or all of the technical features therein; and these modifications or substitutions do not make corresponding technical solutions essentially depart from the scope of the technical solutions of the various embodiments of the present invention.

What is claimed is:

1. A device for testing pressure of keys of a full keyboard, characterized by comprising: a variable-pitch test module mechanism, wherein the variable-pitch test module mechanism comprises a plurality of variable-pitch test modules mounted on a base plate and probe modules provided corresponding to the variable-pitch test modules one by one;
the variable-pitch test module comprises a first driving device and a second driving device, the probe module is mounted on the second driving device, the second driving device is provided on the first driving device, the first driving device is configured to adjust a position of the probe module in an X direction, and the second driving device is configured to adjust a position of the probe module in a Y direction; and
the probe module comprises a lifting device and a probe for testing, wherein the lifting device is connected to the probe and is configured to adjust a position of the probe in a Z direction.

2. The device for testing pressure of keys of a full keyboard according to claim 1, wherein
the base plate is mounted with a guide-shaft fixing plate, the variable-pitch test module further comprises a lead screw module base, the lead screw module base is connected to the base plate, and the first driving device comprises a guide structure and an adjustment structure which are provided between the lead screw module base and the guide-shaft fixing plate.

3. The device for testing pressure of keys of a full keyboard according to claim 2, wherein
the guide structure comprises a bushing and a guide shaft, the bushing being provided in a through hole of the lead screw module base and the guide shaft penetrating through the bushing.

4. The device for testing pressure of keys of a full keyboard according to claim 2, wherein
the adjustment structure comprises an adjustment bolt, the adjustment bolts being connected between the lead screw module base and the guide-shaft fixing plate.

5. The device for testing pressure of keys of a full keyboard according to claim 4, wherein
the guide-shaft fixing plate is provided with a limiting groove for limiting the adjustment bolt in the X direction.

6. The device for testing pressure of keys of a full keyboard according to claim 2, wherein
the second driving device comprises a motor and a lead screw module, wherein the lead screw module is mounted on the lead screw module base, the lead screw module is connected to the probe module, the motor is in transmission connection with the lead screw module, and the motor drives the lead screw module to move in the Y direction.

7. The device for testing pressure of keys of a full keyboard according to claim 6, wherein
the lead screw module is connected to a slider base, the slider base is mounted with a probe module fixing block, and the lifting device is provided on the probe module fixing block.

8. The device for testing pressure of keys of a full keyboard according to claim 7, wherein
the lifting device comprises a guide rail, a pressure sensor fixing block and a pressure sensor, wherein the guide rail is provided on the probe module fixing block, the pressure sensor fixing block is slidably connected to the guide rail, and the pressure sensor has one end connected to the pressure sensor fixing block and the other end connected to the probe.

9. The device for testing pressure of keys of a full keyboard according to claim 8, wherein
a preloaded spring is provided between the probe module fixing block and the pressure sensor fixing block, and the preloaded spring is in a compressed state so as to apply a preloaded force to the probe.

10. The device for testing pressure of keys of a full keyboard according to claim 8, wherein
the probe module fixing block is mounted with a lifting cylinder, wherein the lifting cylinder is connected to the pressure sensor fixing block and is configured to lift the probe to an avoidance height in the Z direction.
